(19) United States
(12) Patent Application Publication
(10) Pub. No.: US 2014/0312978 A1
(43) Pub. Date: Oct. 23, 2014

(54) HIGH-FREQUENCY MODULE

(71) Applicant: Murata Manufacturing Co., Ltd., Nagaokakyo-shi (JP)

(72) Inventor: Hiroyuki NAGAMORI, Nagaokakyo-shi (JP)

(21) Appl. No.: 14/323,116

(22) Filed: Jul. 3, 2014

Related U.S. Application Data
(63) Continuation of application No. PCT/JP2013/052440, filed on Feb. 4, 2013.

(30) Foreign Application Priority Data
Feb. 6, 2012 (JP) 2012-023322

(51) Int. Cl. H03F 3/193; H03F 3/195

(52) U.S. Cl. CPC H03F 3/193; H03F 3/195; H03F 2200/451; H03F 2200/294; H03F 2200/429
USPC 330/295

(57) ABSTRACT

A high-frequency module includes a wiring substrate including an electrode pattern layer and a via electrode, a plurality of amplifier circuits that are configured to respectively amplify signals in different frequency bands received at the input terminal, and a plurality of matching circuits and a plurality of filter circuits that are provided in correspondence with the respective amplifier circuits and that are connected sequentially to output sides of the respective amplifier circuits. A plurality of signal paths that extend from the output sides of the respective amplifier circuits to the antenna terminal through the corresponding matching circuits and the filter circuits are provided. The electrode pattern layer and the via electrode are grounded and at least one of the electrode pattern layer and the via electrode is arranged between the signal paths.

### BACKGROUND OF THE INVENTION

1. Field of the Invention

The present invention relates to a high-frequency module including an amplifier circuit provided on a wiring substrate.

2. Description of the Related Art

Cellular phones employ various communication systems, such as the Global System for Mobile Communications (GSM system), the Digital Cellular System (DCS), the Personal Communication Service (PCS) system, and the like. In accordance with recent wide spread use of cellular phones, a high-frequency module supporting multiple bands has been proposed which enables signal transmission and reception in a plurality of communication systems or communication frequency bands.

Further, to reduce the size of cellular phones, as the high-frequency module described above, a high-frequency module has been proposed which includes an antenna switch circuit and an amplifier circuit for amplifying various transmission signals.

However, with a configuration in which an antenna circuit and an amplifier circuit are provided in a single module, the two circuits need to be arranged close to each other, thereby possibly causing degradation of the high-frequency characteristics of the module due to mutual interference between the signals of the two circuits. Hence, referring to FIG. 6, a technique has been proposed in which, the two circuits are respectively formed in two partitioned regions over all the layers in the stacking direction of the multilayer substrate and the two regions are shielded from each other using grounded shield electrodes and via electrodes (refer to Japanese Unexamined Patent Application Publication No. 2004-166248).

In this case, an antenna switch circuit 501 and an amplifier circuit 502 are respectively formed on the right side and the left side of the module and shield electrodes 503 are formed between the two circuits. Further, in each of the layers in the stacking direction of a multilayer substrate 504, a plurality of via electrodes 505 are formed along the shield electrode 503, and a grounding electrode (ground electrode) formed on the lower layer of the multilayer substrate 504 is connected to the shield electrode 503 through the via conductors 505. With this configuration, noise signals generated in the two circuits are blocked from each other, whereby degradation of the high-frequency characteristics of the module due to mutual interference between the signals of the two circuits is suppressed.

In the above described high-frequency module which supports multiple bands, there may be a case in which a plurality of impedance matching circuits which each perform impedance matching between an amplifier circuit and a signal switching circuit including a switch IC and a plurality of filter circuits for removing signals in undesired frequency bands are provided between the antenna switch circuit and the amplifier circuits, in correspondence with different frequency bands. With the high-frequency module described above, only mutual interference between the noise signals and the like of the antenna switch circuit and the amplifier circuit can be suppressed, and hence, mutual interference among the signals of the plurality of matching circuits and the plurality of filter circuits formed between the antenna switch circuit and the amplifier circuit cannot be suppressed, whereby the high-frequency characteristics of the module may be degraded.

### SUMMARY OF THE INVENTION

Accordingly, preferred embodiments of the present invention provide a high-frequency module that secures isolation among matching circuits and filter circuits corresponding to different frequency bands between the antenna switch circuit and the amplifier circuit in addition to isolation between the amplifier circuit and the antenna switch circuit.

A high-frequency module according to a preferred embodiment of the present invention is configured to amplify a signal received at an input terminal and output the amplified signal to an antenna terminal, and the module includes a wiring substrate in which an electrode pattern layer and a via electrode for interlayer connection connected to the electrode pattern are provided; a plurality of amplifier circuits that are provided on the wiring substrate and that are configured to respectively amplify signals in different frequency bands received at the input terminal; and a plurality of matching circuits and a plurality of filter circuits that are provided on the wiring substrate in correspondence with the respective amplifier circuits and that are connected sequentially to output sides of the respective amplifier circuits. A plurality of signal paths that extend from the output sides of the respective amplifier circuits to the antenna terminal through the corresponding matching circuits and the filter circuits are provided. The electrode pattern layer and the via electrode are grounded and at least one of the electrode pattern layer and the via electrode is arranged between the signal paths in a plan view of the wiring substrate.

With this configuration, since isolation between the signal paths is secured, noise signals radiated from the matching circuits and filter circuits provided on the signal paths are blocked from one another for all the signal paths and degradation of the high-frequency characteristics of the module is significantly reduced or prevented.

It is preferable that the via electrode be one of a plurality via electrodes located along the signal paths. With this configuration, since isolation characteristics between the signal paths are enhanced also in the stacking direction, even when the matching circuits and filter circuits provided on the signal paths are arranged in the stacking direction (inside the wiring substrate), noise signals radiated from the matching circuits and filter circuits are blocked from one another for all the signal paths and degradation of the high-frequency characteristics of the module is significantly reduced or prevented.

In a plan view of the wiring substrate, at least one of the electrode pattern layer and the via electrode may be arranged between a region where the amplifier circuits are arranged and a region where the matching circuits and the filter circuits provided in correspondence with the respective amplifier circuits are arranged.

With this configuration, isolation between the amplifier circuits and the matching circuits and filter circuits provided in correspondence with the amplifier circuits is secured and, hence, noise signals radiated from the amplifier circuits and noise signals radiated from the matching circuits and filter circuits provided in correspondence with the amplifier circuits are blocked from one another, such that degradation of the high-frequency characteristics is further significantly reduced or prevented.

A configuration may be used in which, in each of the signal paths, at least one of the electrode pattern layer and the via electrode is arranged between a region where the matching circuit is arranged and a region where the filter circuit is arranged, in a plan view of the wiring substrate, and the electrode pattern layer or the via electrode is electrically connected to an electronic component that defines a portion of the matching circuit.

With this configuration, since there is no need to separately provide ground electrodes for electric components defining a portion of the matching circuits, the size of the high-frequency module is significantly reduced.

A configuration may be used in which signals in different frequency bands amplified by the respective amplifier circuits include a first signal and a second signal a harmonic component of which overlaps a fundamental component of the first signal, and the matching circuit provided on the signal path corresponding to the first signal and the matching circuit provided on the signal path corresponding to the second signal are spaced apart from each other.

With this configuration, even in the high-frequency module supporting multiple bands such as one frequency band and another frequency band a harmonic component of which overlaps the one frequency band, since the matching circuits through which high-power signals are likely to flow are spaced apart from each other, mutual interference between the two signal paths due to noise signals is effectively reduced or prevented.

A configuration may be used in which a signal switching circuit which is provided on the wiring substrate and to which signals from the filter circuits are input is further provided and the amplifier circuits are spaced apart from the signal switching circuit. With this configuration, mutual interference between noise signals radiated from the amplifier circuits and a noise signal radiated from the signal switching circuit is significantly reduced or prevented, and hence, degradation of the high-frequency characteristics is significantly reduced or prevented.

The signal switching circuit may be a switch IC, for example. With this configuration, a preferred embodiment of the present invention can be applied to a high-frequency module in which the signal switching circuit is a switch IC, for example.

According to various preferred embodiments of the present invention, since at least one of the grounded electrode pattern layer and the via electrode for interlayer connection is arranged between the signal paths through which signals in different frequency bands flow, noise signals leaking from the two signal paths are blocked by the electrode pattern or the via electrode, such that degradation of the high-frequency characteristics due to mutual interference between the different frequency bands is significantly reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a block diagram of a high-frequency module according to a preferred embodiment of the present invention.

FIG. 2 is a plan view of a wiring substrate of the high-frequency module according to a preferred embodiment of the present invention.

FIG. 3 illustrates example electrode pattern layers provided on an inner layer of the wiring substrate of the high-frequency module according to a preferred embodiment of the present invention.

FIG. 4 is an example of a ground electrode provided on an inner layer of the wiring substrate of the high-frequency module according to a preferred embodiment of the present invention.

FIG. 5 is a bottom surface view of the wiring substrate of the high-frequency module according to a preferred embodiment of the present invention.

FIG. 6 is a plan view of a high-frequency module based on an existing technology.

### DETAILED DESCRIPTION OF THE PREFERRED EMBODIMENTS

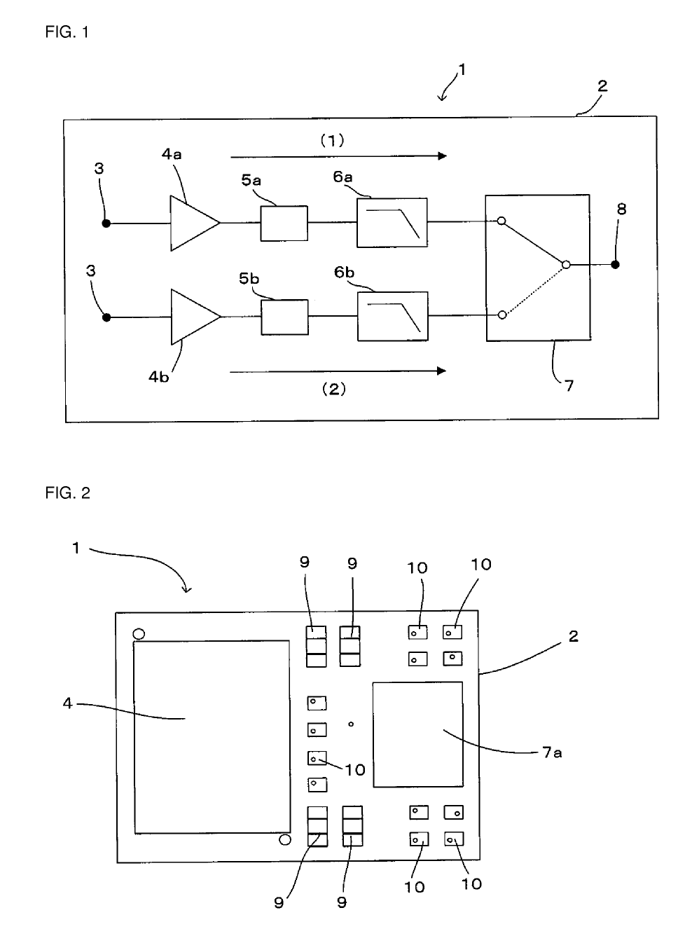

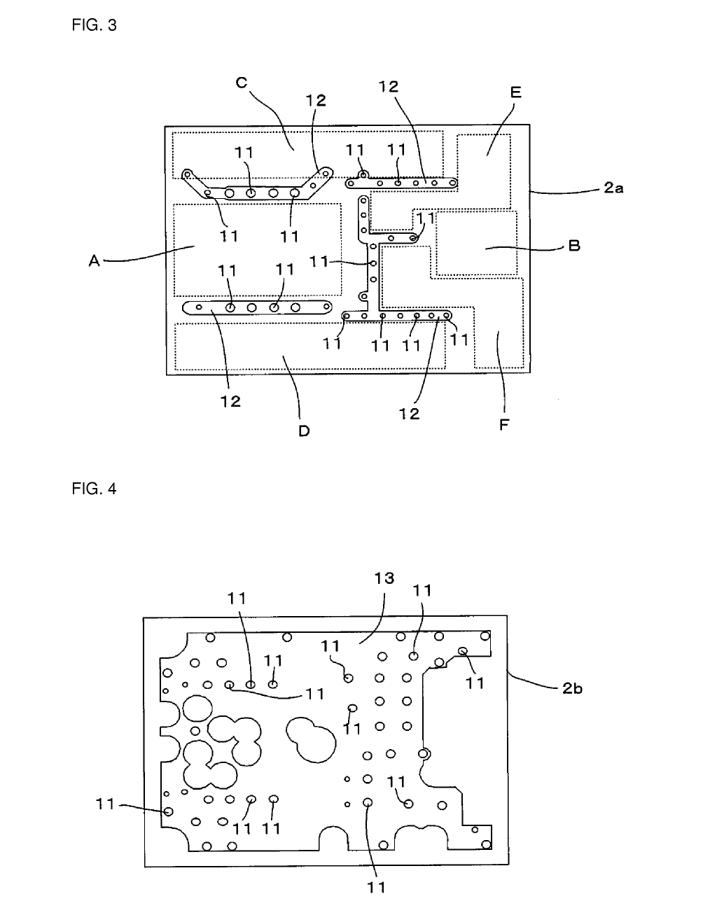

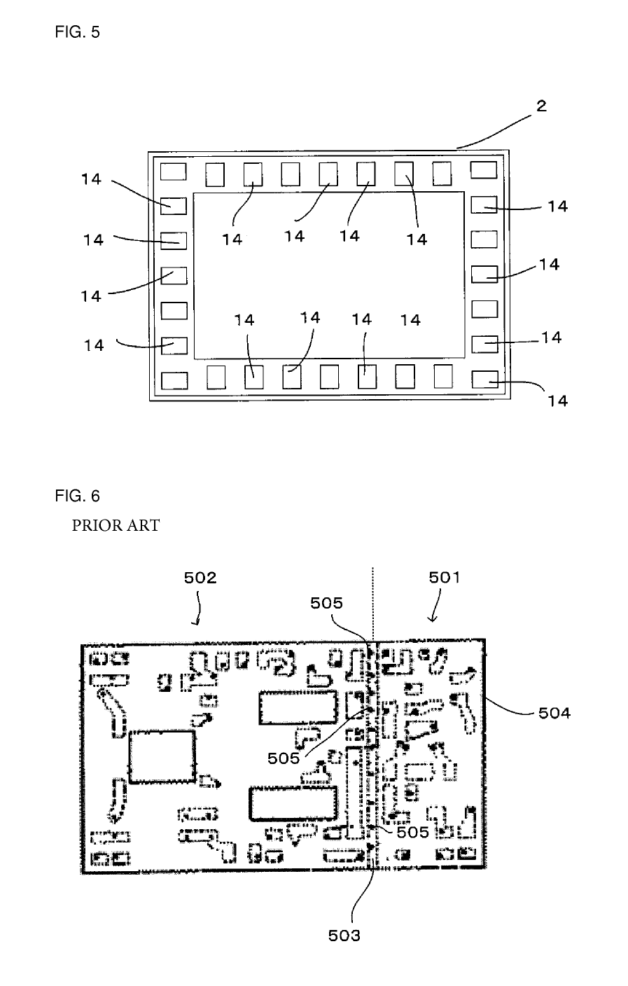

A high-frequency module according to a preferred embodiment of the present invention will be described with reference to FIG. 1 to FIG. 5. FIG. 1 is a block diagram of the high-frequency module according to a preferred embodiment of the present invention, FIG. 2 is a plan view of the high-frequency module, FIG. 3 illustrates example electrode pattern layers formed inside a wiring substrate of the high-frequency module, FIG. 4 is an example of a ground electrode provided inside the wiring substrate, FIG. 5 is a bottom surface view of the high-frequency module, and FIG. 6 is a plan view of a high-frequency module based on an existing technology. It should be noted that some electronic components mounted on the wiring substrate have been omitted in FIG. 2, and illustration of some wiring patterns and via electrodes has been omitted in FIG. 3 and FIG. 4, to simplify the description.

A high-frequency module 1 in the present preferred embodiment preferably is a transmission module which supports multiple bands and receives, at an input terminal 3, signals in the GSM 850 transmission frequency band (824 MHz to 849 MHz), the GSM 900 transmission frequency band (880 MHz to 915 MHz), the DCS 1800 transmission frequency band (1710 MHz to 1785 MHz), and the PCS 1900 transmission frequency band (1850 MHz to 1910 MHz), which are communication standards, amplifies these signals using amplifier circuits 4a and 4b, and outputs them to an antenna terminal 8. The high-frequency module 1 is mounted, for example, on the mother board of a mobile terminal apparatus, such as a cellular phone.

Referring to FIG. 1 regarding a circuit configuration, the high-frequency module 1 includes amplifier circuits 4a and 4b configured to amplify signals in respective frequency bands received at the input terminals 3, matching circuits 5a and 5b configured to perform impedance matching, filter circuits 6a and 6b (LPFs) configured to remove signals in undesired frequency bands, and a signal switching circuit 7 configured to switch transmission signals. The matching circuit 5a and the filter circuit 6a are sequentially connected to the output of the amplifier circuit 4a, such that a signal path (1) is provided. The matching circuit 5b and the filter circuit 6b are sequentially connected to the output of the amplifier circuit 4b, such that a signal path (2) is provided. Signals of the signal paths (1) and (2) are switched between by the signal switching circuit 7 so that one of them is output to the antenna terminal 8. In a non-limiting example, signals of DCS 1800 and PCS 1900 preferably are transmitted using the signal path (1) and signals of GSM 850 and GSM 900 are transmitted using the signal path (2).

Referring to FIG. 2, the high-frequency module 1 according to the present preferred embodiment preferably includes a wiring substrate 2, a power amplifier IC (PA-IC) 4, a switch IC 7a, and electronic components 9 mounted on the front surface of the wiring substrate 2. The PA-IC 4 defines the amplifier circuits 4a and 4b and the switch IC 7a defines the signal switching circuit 7. Electronic components 9 such as a chip inductor, a chip resistor, and a chip capacitor and circuits provided inside the wiring substrate 2 define the matching circuits 5a and 5b. Note that the PA-IC 4 in the present preferred embodiment is configured to amplify a plurality of signals having different frequency bands. The PA-IC 4, the switch IC 7a, and the electronic components 9 are mounted on the wiring substrate 2 preferably using a well-known surface mounting technology, and connected to the wiring substrate 2 using, for example, a solder reflow technology.

The wiring substrate 2 is, for example, a glass epoxy resin multilayer substrate or a low-temperature co-fired ceramic multilayer substrate (LTCC multilayer substrate), and is formed preferably by stacking a plurality of insulating layers made of a glass epoxy resin or a ceramic on top of one another. On the front surface or the back surface of each insulating layer, electrode pattern layers and ground electrodes connected to the ground for blocking noise leaking from wiring patterns and circuits, and the like are formed, and via electrodes 11 for interlayer connection of the wiring patterns on the layers are formed. Referring to FIG. 2, land electrodes configured to mount the electronic components 9 or the like are provided on the front surface of the wiring substrate 2. In this case, the wiring patterns, land electrodes 10, electrode pattern layers 12, and a ground electrode 13 are formed preferably using a photolithography technology. The via electrodes 11 are formed preferably by forming via holes in the insulating layers using a laser process or the like and filling the via holes with conductive paste including Ag, Cu, or the like and sintering the conductive paste.

For example, on an insulating layer 2a, which is one of the insulating layers, the electrode pattern layers 12 configured to inhibit mutual interference between circuits due to noise or the like are provided, as illustrated in FIG. 3. In this case, in a region A surrounded by a dotted line, wiring patterns for the amplifier circuits 4a and 4b are arranged in the stacking direction of the wiring substrate 2. Similarly, wiring patterns for the signal switching circuit are located in a region B, the matching circuit 5a provided on the signal path (1) is located in a region C, the matching circuit 5b provided on the signal path (2) is located in a region D, wiring patterns for the filter circuit 6a provided on the signal path (1) are located in a region E, and wiring patterns for the filter circuit 6b provided on the signal path (2) are located in a region F, each being arranged in the stacking direction of the wiring substrate 2. Note that the electrode pattern layers 12 respectively having the same or substantially the same shapes as the electrode pattern layers 12 on the insulating layer 2a illustrated in FIG. 3 are provided on the plurality of insulating layers of the wiring substrate 2. Referring to FIG. 3, the matching circuit 5a (region C) provided on the signal path (1) and the matching circuit 5b (region D) provided on the signal path (2) are spaced apart from each other, and the amplifier circuits 4a and 4b (PA-IC4) are spaced apart from the signal switching circuit 7 (switch IC 7a).

Referring to FIG. 3, a plurality of the via electrodes 11 configured to provide interlayer connection are arranged along the electrode pattern layers 12 located on the insulation layer, and the insulating layer 2a is connected through the via electrodes to another insulating layer on which the electrode pattern layers 12 respectively having the same or approximately the same shapes as the electrode pattern layers 12 located on the insulating layer 2a illustrated in FIG. 3 are provided. Note that also on other layers having the electrode pattern layers 12 formed thereon, the via electrodes 11 are similarly arranged along the electrode pattern layers, such that the electrode pattern layers 12 respectively provided on the insulating layers are connected to one another through the via electrodes 11.

Note that to obtain a shielding effect using the via electrodes 11, it is preferable that the spacing between the neighboring via electrodes 11 arranged along the electrode pattern layers 12 be a quarter or less of the wavelength of a signal in the highest-frequency band among the plurality of frequency bands used in the high-frequency module 1, for example.

The grounded ground electrode 13 as illustrated in FIG. 4 is provided on an insulating layer 2b which is different from the insulating layer illustrated in FIG. 3. On the insulating layer 2b, a plurality of the via electrodes 11 are located in a region where the ground electrode 13 is located, and portions of them are connected to the electrode pattern layers 12 located on another layer (for example, the insulating layer 2a). In this manner, the electrode pattern layers 12 are connected to the ground electrode 13 through the via electrodes 11. Note that ground electrodes 13 may be arranged over a plurality of the layers.

The electrodes of the electronic components 9 defining a portion of the matching circuits 5a and 5b illustrated in FIG. 2 are electrically connected, for example, to the via electrodes (or the electrode pattern layers 12) arranged between the matching circuit 5a (region C) and the filter circuit 6a (region E) or the via electrodes 11 (or the electrode pattern layers 12) arranged between the matching circuit 5b (region D) and the filter circuit 6b (region F), and these via electrodes 11 and the electrode pattern layers 12 are connected to the grounded ground electrode 13 and, hence, the electrodes of the electronic components 9 are grounded.

As described above, in each of the insulating layers and each of the electrode pattern layers 12, as a result of at least either of the electrode pattern layer 12 or the plurality of via electrodes 11 arranged along the electrode pattern layer 12 being arranged among the circuit formation regions A, B, C, D, E, and F, the regions A, B, C, D, E, and F are partitioned from one another along lines extending in the stacking direction of the wiring substrate 2 and a direction perpendicular or substantially perpendicular to the stacking direction. Specifically, the electrode pattern layers 12 and the via electrodes 11 exist as separators between the signal paths (1) and (2), between the matching circuit 5a and the amplifier circuits 4a and 4b, between the matching circuit 5b and the amplifier circuits 4a and 4b, between the matching circuit 5a and the filter circuit 6a, between the matching circuit 5a and the filter circuit 6b, and between the signal switching circuit 7 and the amplifier circuits 4a and 4b.

As illustrated in FIG. 5, on the bottom surface of the wiring substrate 2, connection electrodes 14 for connection to a mother board are provided, and the high-frequency module 1 is connected to the mother board as a result of the connection electrodes 14 being connected to the mounting electrodes on the mother board through solder or the like.

Hence, according to the preferred embodiment described above, as a result of the electrode pattern layers 12 and the via electrodes 11 connected to the grounded ground electrode 13 being arranged in the stacking direction of the wiring substrate 2 between the regions where the transmission circuits (the signal paths (1) and (2)) having different frequency bands are arranged, the circuit arrangement regions of the signal paths (1) and (2) arranged in the stacking direction of the wiring substrate 2 are partitioned by the electrode pattern layers 12 and the via electrodes 11 having a shielding function and, hence, noise signals leaking from the matching circuits 5a and 5b and the filter circuits 6a and 6b provided on the signal paths (1) and (2) are blocked from one another for the signal paths (1) and (2), such that degradation of the high-frequency characteristics of the high-frequency module 1 is significantly reduced or prevented.

Since the electrode pattern layers 12 and the via electrodes 11 are arranged in the stacking direction of the wiring substrate between the region A where the amplifier circuits 4a and 4b are arranged and the regions C, D, E, and F where the matching circuits 5a and 5b and the filter circuits 6a and 6b respectively provided on the two signal paths (1) and (2) are arranged, noise signals leaking from the amplifier circuits 4a and 4b are blocked, and noise signals from the amplifier circuits 4a and 4b are prevented from being output from the antenna terminal 8 through the matching circuits 5a and 5b or the filter circuits 6a and 6b.

Further, on each of the signal paths (1) and (2), since the electrode pattern layers 12 and the via electrodes 11 are arranged in the stacking direction between a region where the matching circuits 5a and 5b are arranged and a region where the filter circuits 6a and 6b are arranged (between the regions C and E, between the regions D and F), mutual interference between the two circuits is significantly reduced or prevented and degradation of the high-frequency characteristics of the high-frequency module 1 is significantly reduced or prevented.

Since the matching circuits 5a and 5b through which high-power signals are likely to flow are spaced apart from each other, mutual interference between the signal paths (1) and (2) is significantly reduced or prevented. In the present preferred embodiment, since the frequency band (DCS 1800, PCS 1900) of a signal flowing through the signal path (1) overlaps the harmonic components of the frequency band (GSM 850, GSM 900) of a signal flowing through the signal path (2), a signal flowing through the signal path (1) is likely to be influenced by noise from the signal path (2) and, hence, the present preferred embodiment is effective particularly in such a case.

Further, since the amplifier circuits 4a and 4b are spaced apart from the signal switching circuit 7, mutual interference due to signals leaking from the amplifier circuits 4a and 4b and a signal leaking from the signal switching circuit 7 is significantly reduced or prevented, such that degradation of the high-frequency characteristics is significantly reduced or prevented.

Further, since a plurality of the via electrodes 11 connected to the grounded ground electrode 13 are arranged around the PA-IC4 which is likely to generate heat, heat dissipation effect is obtained by these via electrodes 11.

Further, the electrodes of the electronic components 9 which define a portion of matching circuits are electrically connected to the via electrodes 11 (or the electrode pattern layers 12) arranged between the matching circuit 5a (region C) and the filter circuit 6a or to the via electrodes 11 (or the electrode pattern layers 12) arranged between the matching circuit 5b (region D) and the filter circuit 6b (region F). Since the via electrodes 11 and the electrode pattern layers 12 are connected to the ground electrode 13, there is no need to separately provide ground electrodes for the electronic components 9, such that the size of the high-frequency module is significantly reduced.

Note that the present invention is not limited to the preferred embodiments described above, and various modifications, other than those described above, are possible within the scope of the present invention.

For example, although the two signal paths (1) and (2) are provided on the wiring substrate 2 in the preferred embodiments described above, more signal paths may be provided on the wiring substrate 2. In this case, for respective signal paths, by arranging circuits in the stacking direction in the partitioned regions of the wiring substrate 2, the electrode pattern layers 12 and the via electrodes 11 may be arranged among the signal paths in the stacking direction.

Further, the frequency bands used in the high-frequency module 1 may be appropriately changed in accordance with the communication system used, not limited to the above preferred embodiments.

Although the preferred embodiments described above uses a configuration in which the single PA-IC 4 includes a plurality of amplifier circuits configured to respectively amplify signals in different frequency bands, a configuration may be used in which, by providing the PA-IC for each of the different frequency bands, each PA-IC amplifies a signal in a single frequency band.

Preferred embodiments of the present invention preferably are applied to any high-frequency module if a configuration is used in which an amplifier circuit is provided on a wiring substrate.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2: A high-frequency module configured to amplify a signal received at an input terminal and output an amplified signal to an antenna terminal, the high-frequency module comprising:
a wiring substrate including an electrode pattern layer and a via electrode configured to provide interlayer connection, connected to the electrode pattern;
a plurality of amplifier circuits that are provided on the wiring substrate and that are configured to respectively amplify signals received at the input terminal in different frequency bands; and
a plurality of matching circuits and a plurality of filter circuits that are provided on the wiring substrate in correspondence with the respective amplifier circuits and that are connected sequentially to output sides of the respective amplifier circuits; wherein
a plurality of signal paths that extend from the output sides of the respective amplifier circuits to the antenna terminal through the corresponding matching circuits and the filter circuits are provided; and
the electrode pattern layer and the via electrode are grounded and at least one of the electrode pattern layer and the via electrode is arranged between the plurality of signal paths in a plan view of the wiring substrate.

3: The high-frequency module according to claim 2, wherein the via electrode is one of a plurality via electrodes arranged along the plurality of signal paths.

4: The high-frequency module according to claim 2, wherein, in a plan view of the wiring substrate, at least one of the electrode pattern layer and the via electrode is arranged between a region where the amplifier circuits are located and a region where the matching circuits and the filter circuits provided in correspondence with the respective amplifier circuits are located.

5: The high-frequency module according to claim 2, wherein
in each of the plurality of signal paths, at least one of the electrode pattern layer and the via electrode is arranged between a region where the matching circuit is located and a region where the filter circuit is located, in a plan view of the wiring substrate; and
the electrode pattern layer or the via electrode is electrically connected to an electronic component that defines a portion of the matching circuit.

6: The high-frequency module according to claim 2, wherein
signals in different frequency bands amplified by the respective amplifier circuits include a first signal and a second signal a harmonic component of which overlaps a fundamental component of the first signal; and
the matching circuit provided on the signal path corresponding to the first signal and the matching circuit provided on the signal path corresponding to the second signal are spaced apart from each other.

7: The high-frequency module according to claim 2, further comprising:
a signal switching circuit which is provided on the wiring substrate and configured to receive signals from the filter circuits; wherein
the amplifier circuits are spaced apart from the signal switching circuit.

8: The high-frequency module according to claim 7, wherein the signal switching circuit is a switch IC.

9: The high-frequency module according to claim 2, wherein the plurality of filter circuits include low pass filter circuits.

10: The high-frequency module according to claim 2, wherein each of the plurality of signal paths includes a respective one of the plurality of matching circuits and the plurality of filter circuits connected to an output of a respective one of the plurality of amplifier circuits.

11: The high-frequency module according to claim 2, wherein each of the plurality of amplifier circuits includes a power amplifier IC.

12: The high-frequency module according to claim 2, further comprising electronic components mounted on a surface of the wiring substrate.

13: The high-frequency module according to claim 12, wherein the electronic components include at least one of a chip inductor, a chip resistor, and a chip capacitor.

14: The high-frequency module according to claim 3, wherein a spacing between adjacent ones of the via electrodes along the electrode pattern layers is about one quarter or less of a wavelength of a signal in a highest-frequency band among the different frequency bands.

15: The high-frequency module according to claim 2, further comprising plural ones of the via electrode and the electrode pattern layer which are configured to define separators between the plurality of signal paths, between a respective one of the plurality of matching circuits and the plurality of amplifier circuits, between a respective one of the plurality of matching circuits and a respective one of the plurality of filter circuits, and between the signal switching circuit and the plurality of amplifier circuits.

16: A mobile terminal apparatus comprising the high-frequency module according to claim 2.
